(19) United States
(12) Patent Application Publication
(10) Pub. No.: US 2026/0291454 A1
(43) Pub. Date: Sep. 24, 2026

(54) LOW-PASS TO NOTCH RECONFIGURABLE FILTER

(71) Applicant: QUALCOMM Incorporated, San Diego, CA (US)

(72) Inventors: Vahid DABBAGH REZAEI, San Diego, CA (US); Ahmed ABBAS MOHAMED HELMY, San Diego, CA (US)

(21) Appl. No.: 19/087,246

(22) Filed: Mar. 21, 2025

(51) Int. Cl. H03F 3/45; H04B 1/401; H04K 3/00

(52) U.S. Cl. CPC H03F 3/45071; H04K 3/224; H03F 2200/546; H03F 2203/45156; H03F 2203/45526; H04B 1/401

(57) ABSTRACT

Certain aspects of the present disclosure are directed towards a reconfigurable filter. The reconfigurable filter generally includes: an amplifier; a first resistive element and a second resistive element coupled between a first terminal of the amplifier and an input of the reconfigurable filter; a first capacitive element coupled to a first node between the first resistive element and the second resistive element; a second capacitive element and a third capacitive element selectively coupled between the first terminal of the amplifier and the input of the reconfigurable filter; and a third resistive element selectively coupled between an output of the amplifier and a second node between the second capacitive element and the third capacitive element.

### BACKGROUND

### Field of the Disclosure

Certain aspects of the present disclosure generally relate to electronic components and, more particularly, to a reconfigurable filter.

### Description of Related Art

Electronic devices include computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast, and so on. These systems may be capable of supporting communication with multiple users by sharing the available system resources (e.g., time, frequency, and power). Examples of such systems include code division multiple access (CDMA) systems, time division multiple access (TDMA) systems, frequency division multiple access (FDMA) systems, and orthogonal frequency division multiple access (OFDMA) systems (e.g., a Long Term Evolution (LTE) system or a New Radio (NR) system). Wireless devices may include transmitters for processing signals for transmission via antennas and/or receivers for processing signal received via these and/or other antennas. Wireless devices may also include one or more filters. For example, a wireless device may include a baseband filter (BBF) for filtering a baseband signal in a receive path or a transmit path.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide the advantages described herein.

Certain aspects of the present disclosure are directed towards a reconfigurable filter. The reconfigurable filter generally includes: an amplifier; a first resistive element and a second resistive element coupled between a first terminal of the amplifier and an input of the reconfigurable filter; a first capacitive element coupled to a first node between the first resistive element and the second resistive element; a second capacitive element and a third capacitive element selectively coupled between the first terminal of the amplifier and the input of the reconfigurable filter; and a third resistive element selectively coupled between an output of the amplifier and a second node between the second capacitive element and the third capacitive element.

Certain aspects of the present disclosure are directed towards a method for operating a reconfigurable filter. The method generally includes: determining whether to operate the reconfigurable filter as a low-pass filter or a notch filter based on a scenario associated with a device including the reconfigurable filter; and controlling a set of switches of the reconfigurable filter to operate the reconfigurable filter as the low-pass filter or the notch filter based on the determination. The reconfigurable filter may include: an amplifier; a first resistive element and a second resistive element coupled between a first terminal of the amplifier and an input of the reconfigurable filter; a first capacitive element coupled to a first node between the first resistive element and the second resistive element; a second capacitive element and a third capacitive element selectively coupled between the first terminal of the amplifier and the input of the reconfigurable filter; and a third resistive element selectively coupled between an output of the amplifier and a second node between the second capacitive element and the third capacitive element.

Certain aspects of the present disclosure are directed towards a wireless device. The wireless device generally includes: an antenna and a receive chain coupled to the antenna and including a baseband filter (BBF), wherein the BBF includes a reconfigurable filter, the reconfigurable filter including: an amplifier; a first resistive element and a second resistive element coupled between a first terminal of the amplifier and an input of the reconfigurable filter; a first capacitive element coupled to a first node between the first resistive element and the second resistive element; a third resistive element selectively coupled between the first node and an output of the amplifier; and a second capacitive element and a third capacitive element selectively coupled between the first terminal of the amplifier and the input of the reconfigurable filter; and a third resistive element selectively coupled between an output of the amplifier and a second node between the second capacitive element and the third capacitive element.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1 is a diagram of an example wireless communications network, in which certain aspects of the present disclosure may be practiced.

FIG. 2 is a block diagram of an example access point (AP) and example user terminals, in which certain aspects of the present disclosure may be practiced.

FIG. 3 is a block diagram of an example transceiver front end, in which certain aspects of the present disclosure may be practiced.

FIG. 4 illustrates an example reconfigurable filter, in accordance with certain aspects of the present disclosure.

FIG. 5 illustrates the reconfigurable filter of FIG. 4 configured as a twin-T notch (TTN) filter, in accordance with certain aspects of the present disclosure.

FIG. 6 illustrates the reconfigurable filter of FIG. 4 configured as a multi-feedback filter, in accordance with certain aspects of the present disclosure.

FIG. 7 illustrates an example reconfigurable differential filter, in accordance with certain aspects of the present disclosure.

FIG. 8 is a flow diagram illustrating example operations for operating a reconfigurable filter, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed toward a reconfigurable filter. The filter may be configured to operate as a notch filter or a low-pass filter. The notch filter may include or be implemented as a twin-T notch filter, providing a stable filtering response across variations in process, voltage, and temperature (PVT). The low-pass filter may include or be implemented as a multi-feedback filter. In some cases, the reconfigurable filter may be configured as the notch filter to reject a jammer from a close proximity source, as described in more detail herein. By using the reconfigurable filter, the filter's size may be reduced compared to other implementations that use separate low-pass and notch filters.

### Example Wireless Communications

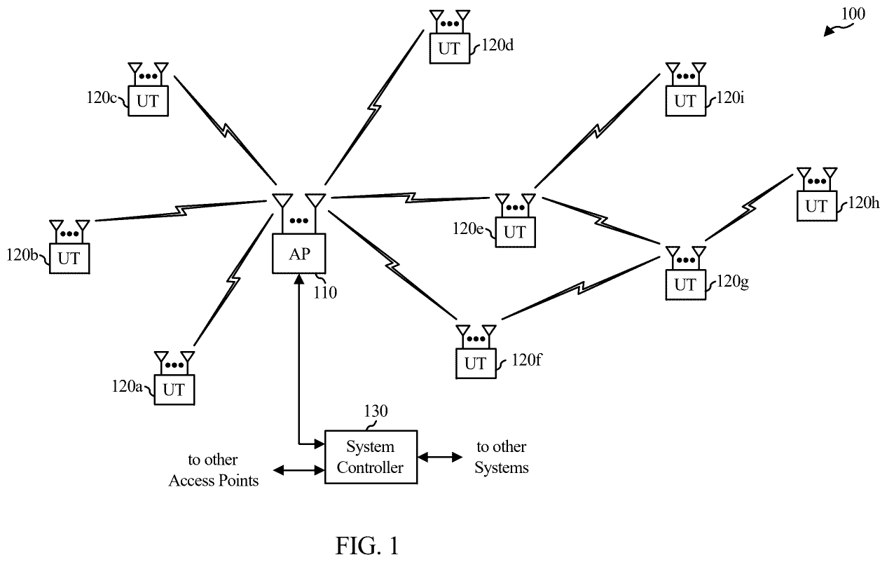

FIG. 1 illustrates a wireless communications system 100 with access points 110 and user terminals 120, in which aspects of the present disclosure may be practiced. For simplicity, only one access point 110 is shown in FIG. 1. An access point (AP) is generally a fixed station that communicates with the user terminals and may also be referred to as a base station (BS), an evolved Node B (eNB), a next generation Node B (gNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

Wireless communications system 100 employs multiple transmit and multiple receive antennas for data transmission on the downlink and uplink. Access point 110 may be equipped with a number Nₐₚ of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas. The Nᵤ selected user terminals can have the same or different number of antennas.

Wireless communications system 100 may be a time division duplex (TDD) system or a frequency division duplex (FDD) system. For a TDD system, the downlink and uplink share the same frequency band. For an FDD system, the downlink and uplink use different frequency bands. Wireless communications system 100 may also utilize a single carrier or multiple carriers for transmission. Each user terminal 120 may be equipped with a single antenna (e.g., to keep costs down) or multiple antennas (e.g., where the additional cost can be supported).

In some aspects, the user terminal 120 or access point 110 may include a reconfigurable filter. The reconfigurable filter may be configured as a low-pass filter or a notch filter, as described in more detail herein.

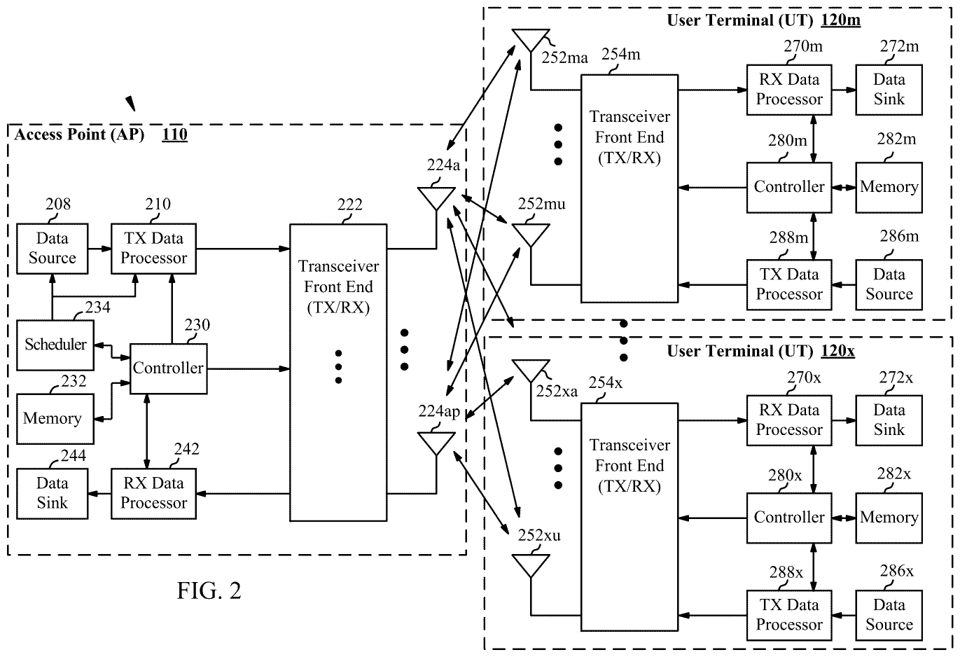

FIG. 2 shows a block diagram of access point 110 and two user terminals 120m and 120x in the wireless communications system 100. Access point 110 is equipped with Nₐₚ antennas 224a through 224ap. User terminal 120m is equipped with N_{ut,m} antennas 252ma through 252mu, and user terminal 120x is equipped with Nᵤₜ, ₓ antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals are selected for simultaneous transmission on the uplink, N_{dn} user terminals are selected for simultaneous transmission on the downlink, Nᵤₚ may or may not be equal to N_{dn}, and Nᵤₚ and N_{dn} may be static values or can change for each scheduling interval. Beam-steering, beamforming, or some other spatial processing technique may be used at the access point and/or user terminal.

On the uplink, at each user terminal 120 selected for uplink transmission, a transmitter (TX) data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ}for one of the N_{ut,m} antennas. A transceiver front end (TX/RX) 254 (also known as a radio frequency front end (RFFE)) receives and processes (e.g., converts to analog, amplifies, filters, and frequency upconverts) a respective symbol stream to generate an uplink signal. The transceiver front end 254 may also route the uplink signal to one of the N_{ut,m} antennas for transmit diversity via a radio frequency (RF) switch, for example. The controller 280 may control the routing within the transceiver front end 254. Memory 282 may store data and program codes for the user terminal 120 and may interface with the controller 280.

A number Nᵤₚ of user terminals 120 may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver front end 222 may select signals received from one of the antennas 224 for processing. The signals received from multiple antennas 224 may be combined for enhanced receive diversity. The access point's transceiver front end 222 also performs processing complementary to that performed by the user terminal's transceiver front end 254 and provides a recovered uplink data symbol stream. The recovered uplink data symbol stream is an estimate of a data symbol stream {sᵤₚ} transmitted by a user terminal. A receiver (RX) data processor 242 processes (e.g., demodulates, deinterleaves, and decodes) the recovered uplink data symbol stream in accordance with the rate used for that stream to obtain decoded data. The decoded data for each user terminal may be provided to a data sink 244 (e.g., corresponding to data sink 272 of UT) for storage and/or a controller 230 for further processing.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal. TX data processor 210 may provide a downlink data symbol streams for one of more of the N_{dn} user terminals to be transmitted from one of the Nₐₚ antennas. The transceiver front end 222 receives and processes (e.g., converts to analog, amplifies, filters, and frequency upconverts) the symbol stream to generate a downlink signal. The transceiver front end 222 may also route the downlink signal to one or more of the Nₐₚ antennas 224 for transmit diversity via an RF switch, for example. The controller 230 may control the routing within the transceiver front end 222. Memory 232 may store data and program codes for the access point 110 and may interface with the controller 230.

At each user terminal 120, N_{ut,m} antennas 252 receive the downlink signals from access point 110. For receive diversity at the user terminal 120, the transceiver front end 254 may select signals received from one or more of the antennas 252 for processing. The signals received from multiple antennas 252 may be combined for enhanced receive diversity. The user terminal's transceiver front end 254 also performs processing complementary to that performed by the access point's transceiver front end 222 and provides a recovered downlink data symbol stream. An RX data processor 270 processes (e.g., demodulates, deinterleaves, and decodes) the recovered downlink data symbol stream to obtain decoded data for the user terminal.

In some aspects, the transceiver front end 254 or 222 may include a reconfigurable filter. The reconfigurable filter may be configured as a low-pass filter or a notch filter, as described in more detail herein.

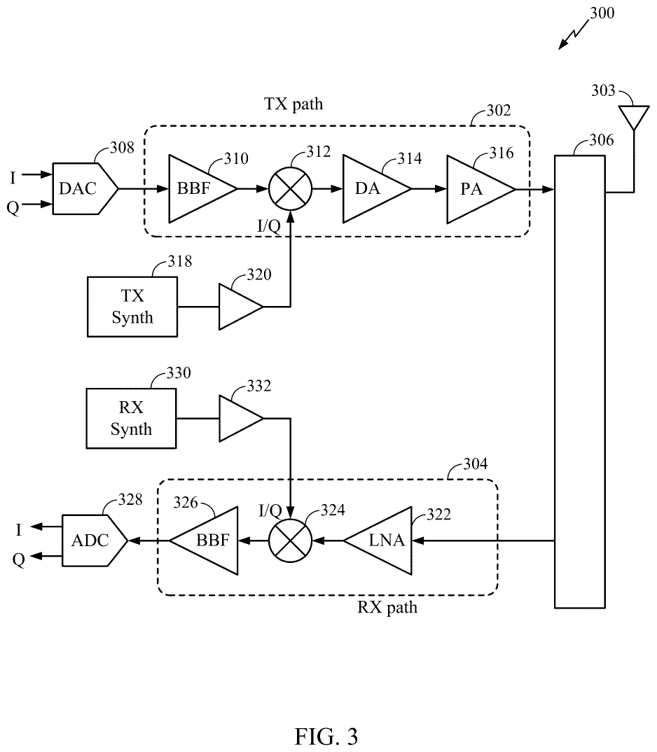

FIG. 3 is a block diagram of an example transceiver front end 300, such as transceiver front ends 222, 254 in FIG. 2, in which aspects of the present disclosure may be practiced. The transceiver front end 300 includes at least one transmit (TX) path 302 (also known as a transmit chain) for transmitting signals via one or more antennas and at least one receive (RX) path 304 (also known as a receive chain) for receiving signals via the one or more antennas. When the TX path 302 and the RX path 304 share an antenna 303, the paths may be connected with the antenna via an interface 306, which may include any of various suitable RF devices, such as a switch, a duplexer, a diplexer, a multiplexer, and the like.

Receiving in-phase (I) or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The BBF 310, the mixer 312, the DA 314, and the PA 316 may be included in a radio frequency integrated circuit (RFIC). In some cases, the PA 316 may be external to the RFIC. In some cases, the DA 314 may include a pre-DA that may drive a DA, where the DA drives the PA 316.

The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency-conversion process produces the sum and difference frequencies of the LO frequency and the frequencies of the baseband signal of interest. The sum and difference frequencies are referred to as the beat frequencies. The beat frequencies are typically in the RF range, such that the signals output by the mixer 312 are typically RF signals, which may be amplified by the DA 314 and/or by the PA 316 before transmission by the antenna 303. While one mixer 312 is illustrated, several mixers may be used to upconvert the filtered baseband signals to one or more intermediate frequencies and to thereafter upconvert the intermediate frequency (IF) signals to a frequency for transmission.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (e.g., downconvert). The baseband signals output by the mixer 324 may be filtered by the BBF 326 before being converted by an analog-to-digital converter (ADC) 328 to digital I and/or Q signals for digital signal processing.

Certain transceivers may employ a variable-frequency oscillator (e.g., a voltage-controlled oscillator (VCO) or a digitally controlled oscillator (DCO)) to generate a stable, tunable LO signal with a particular tuning range. Thus, the transmit LO signal may be produced by a TX frequency synthesizer 318, which may be buffered or amplified by amplifier 320 before being mixed with the baseband signals in the mixer 312. Similarly, the receive LO signal may be produced by an RX frequency synthesizer 330, which may be buffered or amplified by amplifier 332 before being mixed with the RF signals in the mixer 324. For certain aspects, a single-frequency synthesizer may be used for both the TX path 302 and the RX path 304.

In some aspects, the BBF may include a reconfigurable filter. The reconfigurable filter may be configured as a low-pass filter or a notch filter, as described in more detail herein.

While FIGS. 1-3 provide wireless communications as an example application in which certain aspects of the present disclosure may be implemented to facilitate understanding, certain aspects described herein may be used in any of various other suitable systems.

### Example Reconfigurable Filter

In some wireless devices, a baseband filter (BBF) of a transceiver may be designed to cope with many different scenarios in terms of received signal bandwidth (BW) and the proximity of a jammer frequency associated with a jammer signal that is to be rejected. Therefore, the BBF (e.g., BBF 326 of FIG. 3) may be implemented with a combination of filter stages to handle different scenarios. The BBF may support a wide range of bands including narrow bands (e.g., for Global System for Mobile Communications (GSM)) and ultra-wideband technologies with different rejection scenarios. Recent carrier aggregation (CA) technologies result in close-in jammer sources. For example, in one scenario, the BBF may be implemented as a high-quality factor (Q) notch filter so the filter can reject a jammer signal from a close-frequency jammer source (hereinafter referred to as a “close jammer source” or a “close source”) to protect the analog-to-digital converter (ADC) (e.g., ADC 328 of FIG. 3). The notch filter may be implemented via a stand-alone filter stage that takes up a lot of space while only being used for a few specific cases or scenarios. Some devices may use a dedicated active inductor-capacitor (LC) notch (ALN) filter to reject the jammer signal. The ALN filter may be implemented with a low-dropout (LDO) regulator and may only work if used as the last stage of a multi-stage filter. Thus, the ALN filter involves peripheral circuitry (e.g., LDO regulator), and the performance (e.g., filter response) of the ALN filter may vary with process and jammer power level variations.

Certain aspects of the present disclosure are directed towards a reconfigurable filter topology. With the reconfigurable filter, the BBF may be implemented without a dedicated notch filter, reducing the size of the BBF. The reconfigurable filter may be configured as a twin-T notch (TTN) filter to reject a jammer from a close source and configured as a low-pass filter (LPF) otherwise. The LPF may be a multi-feedback filter (e.g., also known as a “Rauch filter”). The TTN filter may provide a high-Q notch filter that is more linear and robust than other filter options. The TTN filter may be an active resistor-capacitor (RC) filter. The performance of the TTN filter may be set by the accuracy of the RC structure (e.g., assuming the supported BW of the operational amplifier of the TTN filter is wide enough).

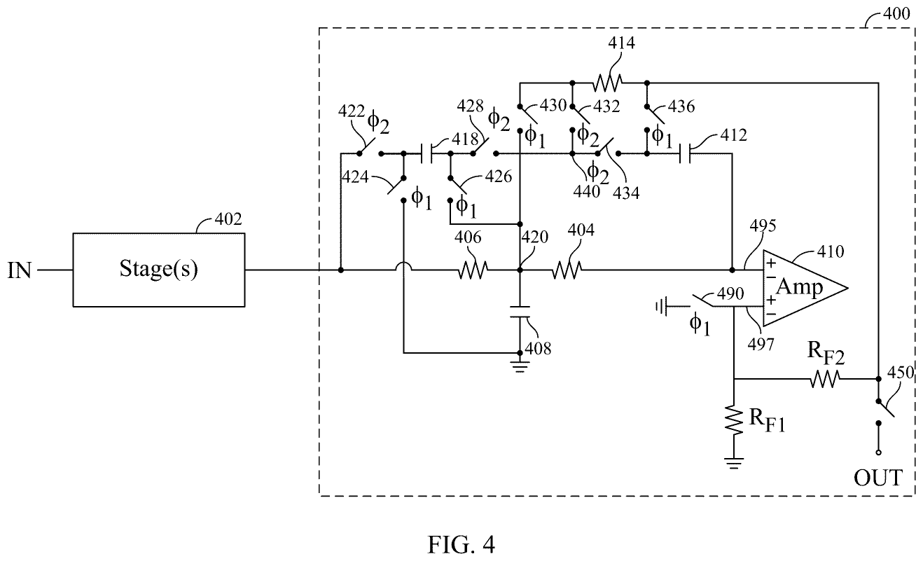

FIG. 4 illustrates an example reconfigurable filter 400, in accordance with certain aspects of the present disclosure. In some cases, the reconfigurable filter 400 may be part of a multi-stage amplifier, with one or more stages 402 coupled between an input of the multi-stage filter and the reconfigurable filter 400.

The reconfigurable filter 400 may include an amplifier 410 (e.g., operational amplifier) and a resistive element 404 coupled between a positive input terminal of the amplifier 410 and a node 420. A capacitive element 408 may be coupled between node 420 and a reference potential node (e.g., electric ground) of the filter. A resistive element 406 may be coupled between node 420 and the input of the reconfigurable filter 400. A first terminal of a capacitive element 418 may be selectively coupled to the input of the filter 400 through a switch 422 and to the reference potential node through a switch 424. A second terminal of the capacitive element 418 may be selectively coupled to the node 420 through a switch 426 and to a node 440 through a switch 428.

A first terminal of a resistive element 414 may be selectively coupled to the node 420 through a switch 430 and to the node 440 through a switch 432. A second terminal of the resistive element 414 may be selectively coupled to a first terminal of a capacitive element 412 through a switch 436 and coupled to an output of the amplifier 410. The first terminal of the capacitive element 412 may be selectively coupled to the node 440 through switch 434. A second terminal of the capacitive element 412 may be coupled to the input terminal 495 of the amplifier 410. In some aspects, a switch 490 may be coupled between the input terminal 497 of amplifier 410 and the reference potential node, as shown. By configuring the amplifier 410 internally, the input terminal 495 may be configured as a positive input terminal and the input terminal 497 may be configured as a negative input terminal, or vice versa.

The filter 400 may include a feedback structure including feedback resistive elements R_{F1} and R_{F2} (e.g., having resistances R_{F1} and R_{F2}, respectively). The resistive element R_{F2} may be coupled between the output of the amplifier 410 and the input terminal 497 of the amplifier 410. The resistive element R_{F1} may be coupled between the input terminal 497 of the amplifier 410 and the reference potential node. The output of the amplifier 410 may be coupled to an output of the filter 400 (e.g., through an enable switch 450).

To configure the filter 400 as a LPF (e.g., multi-feedback filter) during a first phase (Φ₁), the switches 424, 426, 430, 436, 490 may be closed, and switches 422, 428, 432, 434 may be opened. To configure the filter 400 as a TTN filter during a second phase (Φ₂), the switches 422, 428, 432, 434 may be closed, and switches 424, 426, 430, 436, 490 may be opened, as shown by the phase designations in FIG. 4.

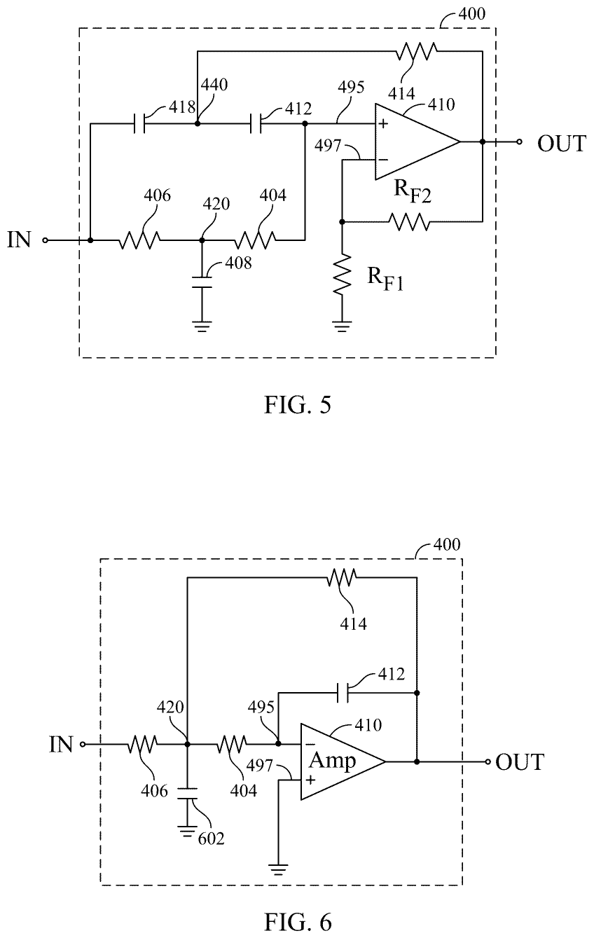

FIG. 5 illustrates the filter 400 configured as a TTN filter, in accordance with certain aspects of the present disclosure. When the filter 400 is configured as a TTN filter, the terminal 495 may be configured as a positive terminal for the amplifier 410 and the terminal 497 may be configured as a negative terminal for the amplifier 410. As shown, the TTN filter includes two T-shaped structures, one including the resistive elements 404, 406 and the capacitive element 408, and another including the capacitive elements 412, 418 and the resistive element 414. The resistive elements 404, 406 are coupled in series between the positive input terminal of the amplifier 410 and the input of the filter 400, where the capacitive element 408 is coupled in shunt to the node 420 between the resistive elements 404, 406. The capacitive elements 412, 418 are coupled in series between the positive input terminal of the amplifier 410 and the input of the filter 400. The resistive element 414 is coupled between the output of the amplifier 410 and the node 440 between the capacitive elements 412, 418.

The resistive elements 404, 406 and capacitive element 408 implement a LPF. The capacitive elements 412, 418 and resistive element 414 implement a high-pass filter (HPF). The LPF and the HPF together effectively implement a notch filter, where the notch frequency is between the cutoff frequency of the LPF and the cutoff frequency of the HPF.

FIG. 6 illustrates the filter 400 configured as a multi-feedback filter (e.g., LPF), in accordance with certain aspects of the present disclosure. When the filter 400 is configured as a multi-feedback filter, the terminal 495 may be configured as a negative terminal for the amplifier 410 and the terminal 497 may be configured as a positive terminal for the amplifier 410. As shown, the filter 400 includes the resistive elements 404, 406 coupled between the positive input terminal of the amplifier 410 and the input of the filter 400. A capacitive element 602 is coupled between the node 420 and the reference potential node. The capacitive element 602 may represent the capacitive element 408 in parallel with the capacitive element 418. That is, referring back to FIG. 4, with switches 424, 426 being closed, the capacitive elements 408, 418 are coupled in parallel and used to implement the capacitive element 602 shown in FIG. 6.

The resistive element 414 may be coupled between node 420 and the output of the amplifier 410, providing a first feedback for the multi-feedback filter. The capacitive element 412 may be coupled between the negative input terminal of the amplifier 410 and the output of the amplifier 410, providing a second feedback for the multi-feedback filter. By closing switch 490 of FIG. 4, the positive input terminal is coupled to the reference potential node.

As described herein, the reconfigurable filter may be operated as a TTN filter or a multi-feedback filter depending on a scenario of a device including the filter. For example, if a jammer source is causing a jammer signal having a nearby frequency that is to be rejected, the reconfigurable filter may be operated as a TTN filter to provide increased rejection and stability with regards to the rejection frequency, allowing the jammer signal to be rejected.

Certain aspects provide a reconfigurable filter that can be used to replace two separate filter stages used in some conventional filter (e.g., BBF) implementations, reducing the size of the filter implementation. When the filter 400 is configured as a TTN filter and due to the TTN filtering being a function of only passive elements, the filter 400 provides a more stable notch frequency over process and temperature variations while also consuming less power, as compared to conventional implementations. The TTN filter may provide increased rejection of a jammer signal, as described.

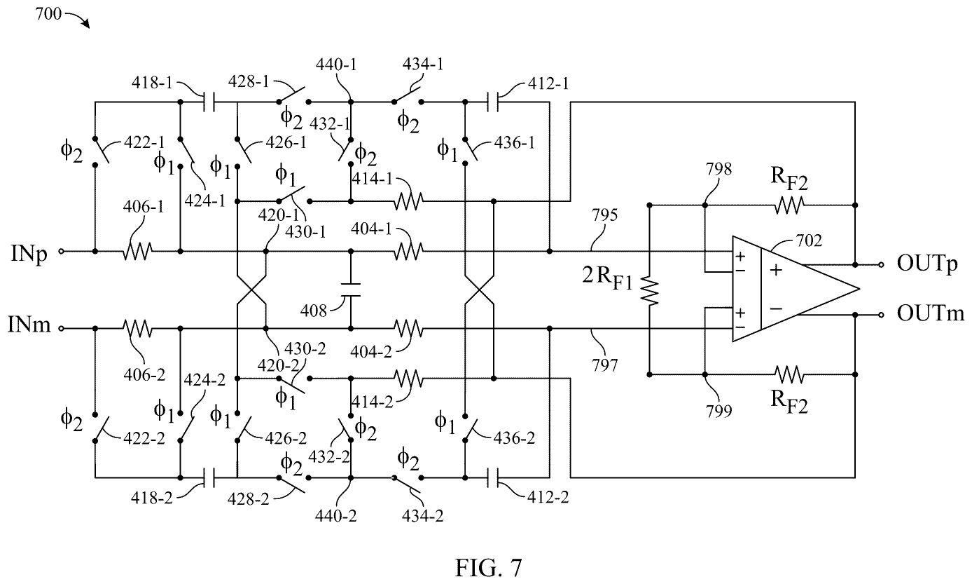

FIG. 7 illustrates an example reconfigurable differential filter 700, in accordance with certain aspects of the present disclosure. The differential filter 700 may be implemented in a similar manner as the single-ended filter 400 described with respect to FIG. 4. As shown, the filter 700 may include a differential amplifier 702 with positive and negative outputs providing respective positive and negative output signals labeled “OUTp” and “OUTm.” The filter 700 also receives positive and negative input signals labeled “INp” and “INm.”

The differential amplifier 702 includes positive terminals 795, 797 and negative terminals 798, 799. For the positive input and output side of the filter 700, the filter 700 may include resistive elements 406-1, 404-1, 414-1 (e.g., corresponding to resistive elements 406, 404, 414 of FIG. 4) and capacitive elements 408, 418-1, 412-1 (e.g., corresponding to capacitive elements 408, 418, 412 of FIG. 4). For the negative input and output side of the filter 700, the filter 700 may include resistive elements 406-2, 404-2, 414-2 (e.g., corresponding to resistive elements 406, 404, 414 of FIG. 4) and capacitive elements 408, 418-2, 412-2 (e.g., corresponding to capacitive elements 408, 418, 412 of FIG. 4).

As shown, the resistive elements 406-1 and 404-1 are coupled between the INp node and the terminal 795. A switch 422-1 is coupled between a first terminal of capacitive element 418-1 and the INp node and a switch 424-1 is coupled between the first terminal of capacitive element 418-1 and node 420-1. A switch 426-1 is coupled between a second terminal of capacitive element 418-1 and node 420-2. A switch 430-1 may be coupled between node 420-2 and a first terminal of resistive element 414-1. A switch 428-1 is coupled between a second terminal of capacitive element 418-1 and node 440-1. A switch 432-1 is coupled between node 440-1 and the first terminal of resistive element 414-1. A switch 434-1 is coupled between node 440-1 and a first terminal of capacitive element 412-1. A switch 436-1 is coupled between the first terminal of capacitive element 412-1 and the OUTm node. The second terminal of capacitive element 412-1 is coupled to the terminal 795, as shown.

As shown, the resistive elements 406-2 and 404-2 are coupled between the INm node and the terminal 797. A switch 422-2 is coupled between a first terminal of capacitive element 418-2 and the INm node and a switch 424-2 is coupled between the first terminal of capacitive element 418-2 and node 420-2. A switch 426-2 is coupled between a second terminal of capacitive element 418-2 and node 420-1. A switch 430-2 may be coupled between node 420-1 and a first terminal of resistive element 414-2. A switch 428-2 is coupled between a second terminal of capacitive element 418-2 and node 440-2. A switch 432-2 is coupled between node 440-2 and the first terminal of resistive element 414-2. A switch 434-2 is coupled between node 440-2 and a first terminal of capacitive element 412-2. A switch 436-2 is coupled between the first terminal of capacitive element 412-2 and the OUTp node. The second terminal of capacitive element 412-2 is coupled to the terminal 797, as shown. The capacitive 408 may be coupled between nodes 420-1 and 420-2.

As shown, a feedback resistive elements having resistances R_{F2} may be coupled between the OUTp and OUTm nodes and terminals 798, 799, respectively. A feedback resistive elements having a resistance of R_{F1}/2 may be coupled between the terminals 798, 799.

To configure the filter 700 as an LPF (e.g., multi-feedback filter) during a first phase (Φ₁), the switches 424-1, 424-2, 426-1, 426-2, 430-1, 430-2, 436-1, 436-2, 490-1, 490-2 may be closed, and switches 422-1, 422-2, 428-1, 428-2, 432, 432-1, 432-2, 434-1, 434-2 may be opened. To configure the filter 700 as a TTN filter during a second phase (Φ₂), the switches 422-1, 422-2, 428-1, 428-2, 432-1, 432-2, 434-1, 434-2 may be closed, and switches 424-1, 424-2, 426-1, 426-2, 430-1, 430-2, 436-1, 436-2, 490-1, 490-2 may be opened, as shown by the phase designations in FIG. 7. When configured as an LPF, the feedback network including the resistive elements labeled “R_{F2}” and the resistive element labeled “R_{F1}/2” may be effectively removed from the filter and the common polarity terminals of the amplifier 702 may be coupled (e.g., shorted) together internally within the amplifier 702. For example, terminal 795 may be coupled to terminal 799 and terminal 798 may be coupled to terminal 797.

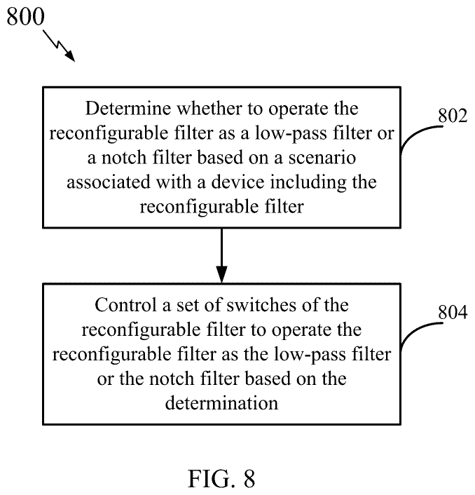

FIG. 8 is a flow diagram illustrating example operations 800 for operating a reconfigurable filter, in accordance with certain aspects of the present disclosure. The operations 800 may be performed, for example, by a controller such as the controller 230 or the controller 280.

At block 802, the controller may determine whether to operate the reconfigurable filter as a low-pass filter (e.g., multi-feedback filter) or a notch filter (e.g., a twin-T notch filter) based on a scenario associated with a device including the reconfigurable filter. For example, the determination of whether to operate the reconfigurable filter as the low-pass filter or the notch filter may be based on a proximity of a jammer source to the device.

At block 804, the controller may control a set of switches of the reconfigurable filter to operate the reconfigurable filter as the low-pass filter or the notch filter based on the determination. In some aspects, the reconfigurable filter includes: an amplifier (e.g., amplifier 410 or amplifier 702); a first resistive element (e.g., resistive element 404 of FIG. 4, resistive element 404-1 of FIG. 7, or resistive element 404-2 of FIG. 7) and a second resistive element (e.g., resistive element 406 of FIG. 4, resistive element 406-1 of FIG. 7, or resistive element 406-2 of FIG. 7) coupled in series between a first terminal of the amplifier and an input of the reconfigurable filter; a first capacitive element (e.g., capacitive element 408 of FIG. 4 or FIG. 7) coupled to a first node (e.g., node 420 of FIG. 4, node 420-1 of FIG. 7, or node 420-2 of FIG. 7) between the first resistive element and the second resistive element; a second capacitive element (e.g., capacitive element 412 of FIG. 4, capacitive element 412-2 of FIG. 7, or capacitive element 412-2 of FIG. 7) and a third capacitive element (e.g., capacitive element 418 of FIG. 4, capacitive element 418-1 of FIG. 7, or capacitive element 418-2 of FIG. 7) selectively coupled between the first terminal of the amplifier and the input of the reconfigurable filter; a third resistive element (e.g., resistive element 414 of FIG. 4, resistive element 414-1 of FIG. 7, or resistive element 414-2 of FIG. 7) selectively coupled between an output of the amplifier and a second node (e.g., node 440 of FIG. 4, node 440-1 of FIG. 7, or node 440-2 of FIG. 7) between the second capacitive element and the third capacitive element. In some aspects, the reconfigurable filter further comprises a feedback network (e.g., including feedback resistive elements R_{F1} and R_{F2}) coupled between the output of the amplifier and a second terminal of the amplifier.

In some aspects, the set of switches includes: a first switch (e.g., switch 422 of FIG. 4, switch 422-1 of FIG. 7, or switch 422-2 of FIG. 7) coupled between a first terminal of the third capacitive element and the input; a second switch (e.g., switch 428 of FIG. 4, switch 428-1 of FIG. 7, or switch 428-2 of FIG. 7) and a third switch (e.g., switch 432 of FIG. 4, switch 432-1 of FIG. 7, or switch 432-2 of FIG. 7) coupled between a second terminal of the third capacitive element and a first terminal of the third resistive element; and a fourth switch (e.g., switch 434 of FIG. 4, switch 434-1 of FIG. 7, or switch 434-2 of FIG. 7) coupled between a first terminal of the second capacitive element and the second node between the second switch and the third switch, a second terminal of the second capacitive element being coupled to the first terminal of the amplifier. To control the set of switches, the controller may close the first switch, the second switch, the third switch, and the fourth switch to operate the reconfigurable filter as the notch filter.

In some aspects, the set of switches includes: a first switch (e.g., switch 430 of FIG. 4, switch 430-1 of FIG. 7, or switch 4301-2 of FIG. 7) coupled between the first node and a first terminal of the third resistive element; and a second switch (e.g., switch 436 of FIG. 4, switch 436-1 of FIG. 7, or switch 436-2 of FIG. 7) coupled between a second terminal of the third resistive element and a first terminal of the second capacitive element. The set of switches may also include: a third switch (e.g., switch 424 of FIG. 4, switch 424-1 of FIG. 7, or switch 424-2 of FIG. 7) coupled to a first terminal of the third capacitive element; and a fourth switch (e.g., switch 426 of FIG. 4, switch 426-1 of FIG. 7, or switch 426-2 of FIG. 7) coupled between a second terminal of the third capacitive element and the first node. In some aspects, to control the set of switches, the controller may close the first switch and the second switch to operate the reconfigurable filter as the low-pass filter.

### EXAMPLE ASPECTS

Aspect 1: A reconfigurable filter, comprising: an amplifier; a first resistive element and a second resistive element coupled between a first terminal of the amplifier and an input of the reconfigurable filter; a first capacitive element coupled to a first node between the first resistive element and the second resistive element; a second capacitive element and a third capacitive element selectively coupled between the first terminal of the amplifier and the input of the reconfigurable filter; and a third resistive element selectively coupled between an output of the amplifier and a second node between the second capacitive element and the third capacitive element.

Aspect 2: The reconfigurable filter of Aspect 1, further comprising a feedback network coupled between the output of the amplifier and a second terminal of the amplifier.

Aspect 3: The reconfigurable filter of Aspect 1 or 2, further comprising: a first switch coupled between a first terminal of the third capacitive element and the input; a second switch and a third switch coupled between a second terminal of the third capacitive element and a first terminal of the third resistive element, a second terminal of the third resistive element being coupled to the output of the amplifier; and a fourth switch coupled between a first terminal of the second capacitive element and the second node between the second switch and the third switch, a second terminal of the second capacitive element being coupled to the first terminal of the amplifier.

Aspect 4: The reconfigurable filter of Aspect 3, wherein the first switch, the second switch, the third switch, and the fourth switch are configured to be closed to operate the reconfigurable filter as a twin-T notch filter.

Aspect 5: The reconfigurable filter of Aspect 3 or 4, further comprising: a fifth switch coupled between the first node and the first terminal of the third resistive element; and a sixth switch coupled between the second terminal of the third resistive element and the first terminal of the second capacitive element.

Aspect 6: The reconfigurable filter of Aspect 5, further comprising: a seventh switch coupled to the first terminal of the third capacitive element; and an eighth switch coupled between the second terminal of the third capacitive element and the first node, the first node being coupled to the second terminal of the first capacitive element, wherein: the first switch, the second switch, the third switch, and the fourth switch are configured to be closed and the fifth switch, the sixth switch, the seventh switch, and the eighth switch are configured to be open to operate the reconfigurable filter as a twin-T notch filter; and the first switch, the second switch, the third switch, and the fourth switch are configured to be open and the fifth switch, the sixth switch, the seventh switch, and the eighth switch are configured to be closed to operate the reconfigurable filter as a multi-feedback filter.

Aspect 7: The reconfigurable filter according to any of Aspects 1-6, further comprising: a first switch coupled between the first node and a first terminal of the third resistive element; and a second switch coupled between a second terminal of the third resistive element and a first terminal of the second capacitive element.

Aspect 8: The reconfigurable filter of Aspect 7, further comprising: a third switch coupled to a first terminal of the third capacitive element; and a fourth switch coupled between a second terminal of the third capacitive element and the first node.

Aspect 9: The reconfigurable filter of Aspect 7 or 8, wherein the first switch and the second switch are configured to be closed to operate the reconfigurable filter as a multi-feedback filter.

Aspect 10: The reconfigurable filter according to any of Aspects 1-9, further comprising a set of switches configured to selectively operate the reconfigurable filter as a twin-T notch filter or a multi-feedback filter.

Aspect 11: The reconfigurable filter according to any of Aspects 1-10, wherein the reconfigurable filter is configured to operate as a twin-T notch filter based on a proximity of a jammer frequency to a channel bandwidth.

Aspect 12: A method for operating a reconfigurable filter, comprising: determining whether to operate the reconfigurable filter as a low-pass filter or a notch filter based on a scenario associated with a device including the reconfigurable filter; and controlling a set of switches of the reconfigurable filter to operate the reconfigurable filter as the low-pass filter or the notch filter based on the determination, wherein the reconfigurable filter includes: an amplifier; a first resistive element and a second resistive element coupled between a first terminal of the amplifier and an input of the reconfigurable filter; a first capacitive element coupled to a first node between the first resistive element and the second resistive element; a second capacitive element and a third capacitive element selectively coupled between the first terminal of the amplifier and the input of the reconfigurable filter; and a third resistive element selectively coupled between an output of the amplifier and a second node between the second capacitive element and the third capacitive element.

Aspect 13: The method of Aspect 12, wherein the reconfigurable filter further comprises a feedback network coupled between the output of the amplifier and a second terminal of the amplifier.

Aspect 14: The method of Aspect 12 or 13, wherein the set of switches includes: a first switch coupled between a first terminal of the third capacitive element and the input; a second switch and a third switch coupled between a second terminal of the third capacitive element and a first terminal of the third resistive element; and a fourth switch coupled between a first terminal of the second capacitive element and the second node between the second switch and the third switch, a second terminal of the second capacitive element being coupled to the first terminal of the amplifier.

Aspect 15: The method of Aspect 14, wherein controlling the set of switches comprises closing the first switch, the second switch, the third switch, and the fourth switch to operate the reconfigurable filter as the notch filter.

Aspect 16: The method according to any of Aspects 12-15, wherein the set of switches comprises: a first switch coupled between the first node and a first terminal of the third resistive element; and a second switch coupled between a second terminal of the third resistive element and a first terminal of the second capacitive element.

Aspect 17: The method of Aspect 16, wherein the set of switches further comprises: a third switch coupled between a first terminal of the third capacitive element and the reference potential node; and a fourth switch coupled between a second terminal of the third capacitive element and the first node.

Aspect 18: The method of Aspect 16 or 17, wherein controlling the set of switches comprises closing the first switch and the second switch to operate the reconfigurable filter as the low-pass filter.

Aspect 19: The method according to any of Aspects 12-18, wherein the determination of whether to operate the reconfigurable filter as the low-pass filter or the notch filter is based on a proximity of a jammer frequency to a channel bandwidth.

Aspect 20: A wireless device, comprising: an antenna; and a receive chain coupled to the antenna and including a baseband filter (BBF), wherein the BBF includes a reconfigurable filter, the reconfigurable filter including: an amplifier; a first resistive element and a second resistive element coupled between a first terminal of the amplifier and an input of the reconfigurable filter; a first capacitive element coupled to a first node between the first resistive element and the second resistive element; a second capacitive element and a third capacitive element selectively coupled between the first terminal of the amplifier and the input of the reconfigurable filter; and a third resistive element selectively coupled between an output of the amplifier and a second node between the second capacitive element and the third capacitive element.

### Additional Considerations

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

1. A reconfigurable filter, comprising:
an amplifier;
a first resistive element and a second resistive element coupled between a first terminal of the amplifier and an input of the reconfigurable filter;
a first capacitive element coupled to a first node between the first resistive element and the second resistive element;
a second capacitive element and a third capacitive element selectively coupled between the first terminal of the amplifier and the input of the reconfigurable filter; and
a third resistive element selectively coupled between an output of the amplifier and a second node between the second capacitive element and the third capacitive element.

2. The reconfigurable filter of claim 1, further comprising a feedback network coupled between the output of the amplifier and a second terminal of the amplifier.

3. The reconfigurable filter of claim 1, further comprising:
a first switch coupled between a first terminal of the third capacitive element and the input;
a second switch and a third switch coupled between a second terminal of the third capacitive element and a first terminal of the third resistive element, a second terminal of the third resistive element being coupled to the output of the amplifier; and
a fourth switch coupled between a first terminal of the second capacitive element and the second node between the second switch and the third switch, a second terminal of the second capacitive element being coupled to the first terminal of the amplifier.

4. The reconfigurable filter of claim 3, wherein the first switch, the second switch, the third switch, and the fourth switch are configured to be closed to operate the reconfigurable filter as a twin-T notch filter.

5. The reconfigurable filter of claim 3, further comprising:
a fifth switch coupled between the first node and the first terminal of the third resistive element; and
a sixth switch coupled between the second terminal of the third resistive element and the first terminal of the second capacitive element.

6. The reconfigurable filter of claim 5, further comprising:
a seventh switch coupled to the first terminal of the third capacitive element; and
an eighth switch coupled between the second terminal of the third capacitive element and the first node, the first node being coupled to the second terminal of the first capacitive element, wherein:
the first switch, the second switch, the third switch, and the fourth switch are configured to be closed and the fifth switch, the sixth switch, the seventh switch, and the eighth switch are configured to be open to operate the reconfigurable filter as a twin-T notch filter; and
the first switch, the second switch, the third switch, and the fourth switch are configured to be open and the fifth switch, the sixth switch, the seventh switch, and the eighth switch are configured to be closed to operate the reconfigurable filter as a multi-feedback filter.

7. The reconfigurable filter of claim 1, further comprising:
a first switch coupled between the first node and a first terminal of the third resistive element; and
a second switch coupled between a second terminal of the third resistive element and a first terminal of the second capacitive element.

8. The reconfigurable filter of claim 7, further comprising:
a third switch coupled to a first terminal of the third capacitive element; and
a fourth switch coupled between a second terminal of the third capacitive element and the first node.

9. The reconfigurable filter of claim 7, wherein the first switch and the second switch are configured to be closed to operate the reconfigurable filter as a multi-feedback filter.

10. The reconfigurable filter of claim 1, further comprising a set of switches configured to selectively operate the reconfigurable filter as a twin-T notch filter or a multi-feedback filter.

11. The reconfigurable filter of claim 1, wherein the reconfigurable filter is configured to operate as a twin-T notch filter based on a proximity of a jammer frequency to a channel bandwidth.

12. A method for operating a reconfigurable filter, comprising:
determining whether to operate the reconfigurable filter as a low-pass filter or a notch filter based on a scenario associated with a device including the reconfigurable filter; and
controlling a set of switches of the reconfigurable filter to operate the reconfigurable filter as the low-pass filter or the notch filter based on the determination, wherein the reconfigurable filter includes:
an amplifier;
a first resistive element and a second resistive element coupled between a first terminal of the amplifier and an input of the reconfigurable filter;
a first capacitive element coupled to a first node between the first resistive element and the second resistive element;
a second capacitive element and a third capacitive element selectively coupled between the first terminal of the amplifier and the input of the reconfigurable filter; and
a third resistive element selectively coupled between an output of the amplifier and a second node between the second capacitive element and the third capacitive element.

13. The method of claim 12, wherein the reconfigurable filter further comprises a feedback network coupled between the output of the amplifier and a second terminal of the amplifier.

14. The method of claim 12, wherein the set of switches includes:
a first switch coupled between a first terminal of the third capacitive element and the input;
a second switch and a third switch coupled between a second terminal of the third capacitive element and a first terminal of the third resistive element; and
a fourth switch coupled between a first terminal of the second capacitive element and the second node between the second switch and the third switch, a second terminal of the second capacitive element being coupled to the first terminal of the amplifier.

15. The method of claim 14, wherein controlling the set of switches comprises closing the first switch, the second switch, the third switch, and the fourth switch to operate the reconfigurable filter as the notch filter.

16. The method of claim 12, wherein the set of switches comprises:
a first switch coupled between the first node and a first terminal of the third resistive element; and
a second switch coupled between a second terminal of the third resistive element and a first terminal of the second capacitive element.

17. The method of claim 16, wherein the set of switches further comprises:
a third switch coupled between a first terminal of the third capacitive element and the reference potential node; and
a fourth switch coupled between a second terminal of the third capacitive element and the first node.

18. The method of claim 16, wherein controlling the set of switches comprises closing the first switch and the second switch to operate the reconfigurable filter as the low-pass filter.

19. The method of claim 12, wherein the determination of whether to operate the reconfigurable filter as the low-pass filter or the notch filter is based on a proximity of a jammer frequency to a channel bandwidth.

20. A wireless device, comprising:
an antenna; and
a receive chain coupled to the antenna and including a baseband filter (BBF), wherein the BBF includes a reconfigurable filter, the reconfigurable filter including:
an amplifier;
a first resistive element and a second resistive element coupled between a first terminal of the amplifier and an input of the reconfigurable filter;
a first capacitive element coupled to a first node between the first resistive element and the second resistive element;
a second capacitive element and a third capacitive element selectively coupled between the first terminal of the amplifier and the input of the reconfigurable filter; and
a third resistive element selectively coupled between an output of the amplifier and a second node between the second capacitive element and the third capacitive element.
